(19) United States
(12) Patent Application Publication
(10) Pub. No.: US 2016/0190157 A1
(43) Pub. Date: Jun. 30, 2016

(54) PIXEL STRUCTURE AND MANUFACTURING METHOD THEREOF

(71) Applicant: SHENZHEN CHINA STAR OPTOELECTRONICS TECHNOLOGY CO. LTD., Shenzhen, Guangdong (CN)

(72) Inventor: Yuejun TANG, Guangdong (CN)

(21) Appl. No.: 14/417,514

(22) PCT Filed: Jan. 7, 2015
(86) PCT No.: PCT/CN2015/070273

§ 371 Date: Jan. 26, 2015

(30) Foreign Application Priority Data
Dec. 30, 2014 (CN) 201410853614.4

(51) Int. Cl. H01L 27/12; H01L 29/786; H01L 29/66; H01L 29/417

(52) U.S. Cl. CPC H01L 27/124; H01L 27/1222; H01L 27/1248; H01L 27/1262; H01L 27/127; H01L 29/41733; H01L 29/41758; H01L 29/78696; H01L 29/78606; H01L 29/78669; H01L 29/66765

(57) ABSTRACT

A TFT-LCD pixel structure and a manufacturing method thereof are provided. The TFT-LCD pixel structure includes a gate line, a TFT switch and a pixel electrode that are formed on a substrate. The TFT switch includes a circular drain, an annular semiconductor layer, an annular source, and a protective layer. The circular drain is insulatively formed on the gate line. The annular semiconductor layer is disposed around the circular drain. The annular source is disposed around the annular semiconductor layer. The protective layer is formed on the circular drain, the annular semiconductor layer, and the annular source, in which the protective layer defines a via hole on the circular drain, and the pixel electrode is electrically coupled to the circular drain through the via hole. The TFT-LCD pixel structure of the present invention can enhance aperture ratio and increase charging capability of the pixel electrode.

### TECHNICAL FIELD OF THE INVENTION

The present invention relates to a liquid crystal display (LCD) technology, and in particular to a thin film transistor liquid crystal display (TFT-LCD) pixel structure and a manufacturing method thereof.

### BACKGROUND OF THE INVENTION

With continuous advancement in LCD technology, the number of pixels on a thin-film transistor (TFT) array substrate gradually increases. That is to say, pixels per inch (PPI) on the display panel also simultaneously increases. Therefore, the number of the TFTs that control brightness of every pixel also goes on increasing.

However, under the same area, more and more TFT switches and a plurality of gate lines and data lines need to be disposed thereon, such that an aperture ratio of the liquid crystal panel gradually decreases. In order to increase the aperture ratio, the TFT switches are manufactured to be smaller. This would cause charging capability of pixel electrodes to be put to the test. FIG. 1 is a schematic sectional view illustrating a conventional TFT-LCD pixel structure. As shown in FIG. 1, a TFT switch 10 includes a gate 11, a source 12 coupled to a data line, and a drain 13 coupled to a pixel electrode 15. A protective layer (abbreviated to OC (Over Coat) layer 17) with a predetermined thickness has to be disposed on the TFT switch 10. An electrical connection between the pixel electrode 15 and the drain 13 is realized through a via hole 19. However, the drain 13 of the reduced TFT switch 10 is also reduced, thus making a connecting region of the pixel electrode 15 and the drain 13 also simultaneously reduced. This will affect conductivity of the pixel electrode 15 and lower the charging capability of the pixel electrode 15. Meanwhile, since the OC layer 17 is too big, the via hole 19 is larger. This will hinder the improvement of the aperture ratio of the pixel.

### SUMMARY OF THE INVENTION

An objective of the present invention is to provide a TFT-LCD pixel structure, which disposes the source and drain of a TFT switch on a gate line for enhancing the aperture ratio. In addition, the present invention designs the drain to be circular and designs the source to be an annulus around the drain, so that a contact area between a pixel electrode and the drain increases, so as to enhance charging capability of the pixel electrode.

Another objective of the present invention is to provide a TFT-LCD array substrate, which disposes the source and drain of a TFT switch on a gate line for enhancing the aperture ratio. Meanwhile, the drain is designed to be circular, so that the contact area between a pixel electrode and the drain increases, so as to enhance charging capability of the pixel electrode.

Yet another objective of the present invention is to provide a method for manufacturing a TFT-LCD pixel structure, which provides the specific steps of manufacturing the above-mentioned TFT-LCD pixel structure, thereby solving the drawback in the conventional panel.

To solve the above-mentioned drawback, a preferred embodiment of the present invention provides a TFT-LCD pixel structure, which includes a gate line, a TFT switch and a pixel electrode formed on a substrate. The TFT switch includes a circular drain, an annular semiconductor layer, an annular source, and a protective layer. The circular drain is insulatively formed on the gate line. The annular semiconductor layer is disposed around the circular drain. The annular source is disposed around the annular semiconductor layer. The protective layer is formed on the circular drain, the annular semiconductor layer, and the annular source, wherein the protective layer defines a via hole on the circular drain, and the pixel electrode is electrically coupled to the circular drain through the via hole.

In the preferred embodiment of the present invention, a size of the via hole is about equal to a size of the circular drain. Preferably, the via hole is circular.

In the preferred embodiment the present invention, the gate line has a predetermined width and defines a strip of shaded region. More specifically, the circular drain, the annular semiconductor layer and the annular source are located within the strip of shaded region. In addition, the gate line has a gate insulation layer disposed thereon, and the circular drain, annular semiconductor layer and annular source are formed on the gate insulation layer.

In the preferred embodiment the present invention, the circular drain defines an opening at a center of the circular drain, and the opening is connected to the via hole.

In the preferred embodiment the present invention, the annular semiconductor layer includes an annular active layer, a first annular ohmic contact layer, and a second annular ohmic contact layer. The first annular ohmic contact layer is disposed on an inner edge of the annular active layer and utilized to contact the circular drain. The second annular ohmic contact layer is disposed on an outer edge of the annular active layer and utilized to contact the annular source.

Another preferred embodiment of the present invention provides a TFT-LCD array substrate, which includes a plurality of gate lines, data lines, TFT switches and pixel electrodes formed on the substrate. Each of the TFT switches includes: a circular drain insulatively formed on the gate line; an annular semiconductor layer disposed around the circular drain; an annular source disposed around the annular semiconductor layer; and a protective layer formed on the circular drain, the annular semiconductor layer and the annular source, wherein the protective layer defines a via hole on the circular drain, and the pixel electrode is electrically coupled to the circular drain through the via hole.

In the preferred embodiment of the present invention, the data line is coupled to an outer edge of the annular source.

Similarly, to solve the above-mentioned drawback, yet another preferred embodiment of the present invention provides a method for manufacturing a TFT-LCD pixel structure, which includes the steps of: forming a gate line on a substrate; forming a gate insulation layer on the gate line; forming a circular drain and an annular source disposed around the circular drain on the gate insulation layer by a photo-mask process; forming an annular semiconductor layer located between the circular drain and the annular source on the gate insulation layer; forming a protective layer located on the circular drain, the annular semiconductor layer and the annular source, wherein the protective layer defines a via hole on the circular drain; and forming a pixel electrode on the protective layer, wherein the pixel electrode is electrically coupled to the circular drain through the via hole.

In the preferred embodiment the present invention, the step of forming the annular semiconductor layer includes: forming an ohmic contact layer by a coating process; patterning the ohmic contact layer to form a first annular ohmic contact layer that contacts an outer edge of the circular drain and a second annular ohmic contact layer that contacts an inner edge of the annular source; and forming an annular active layer located between the first annular ohmic contact layer and the second annular ohmic contact layer.

In comparison with the prior art, the present invention arranges the source, drain and semiconductor layer on the same plane, and the source, drain and semiconductor layer of the TFT switch appear a design of concentric circles. Then the circular drain, annular semiconductor layer and annular source of the present invention are disposed on the gate line, and the via hole is directly made above the circular drain for enhancing the aperture ratio. In addition, the circular drain and the annular source of the present invention increases the area of a conduction channel, thereby enhancing charging capability of the pixel electrode.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a schematic sectional view illustrating a conventional TFT-LCD pixel structure;

FIG. 2 is a partial top view schematically illustrating a TFT-LCD pixel structure according to a preferred embodiment of the present invention;

FIG. 3 is a sectional view along a dashed line A-A of FIG. 2;

FIG. 4 is a partial sectional view schematically illustrating a TFT-LCD pixel structure according to a preferred embodiment of the present invention;

FIG. 5 is a partial sectional view illustrating another embodiment; and

FIG. 6 is a flow chart illustrating a method for manufacturing the TFT-LCD pixel structure according to a preferred embodiment of the present invention.

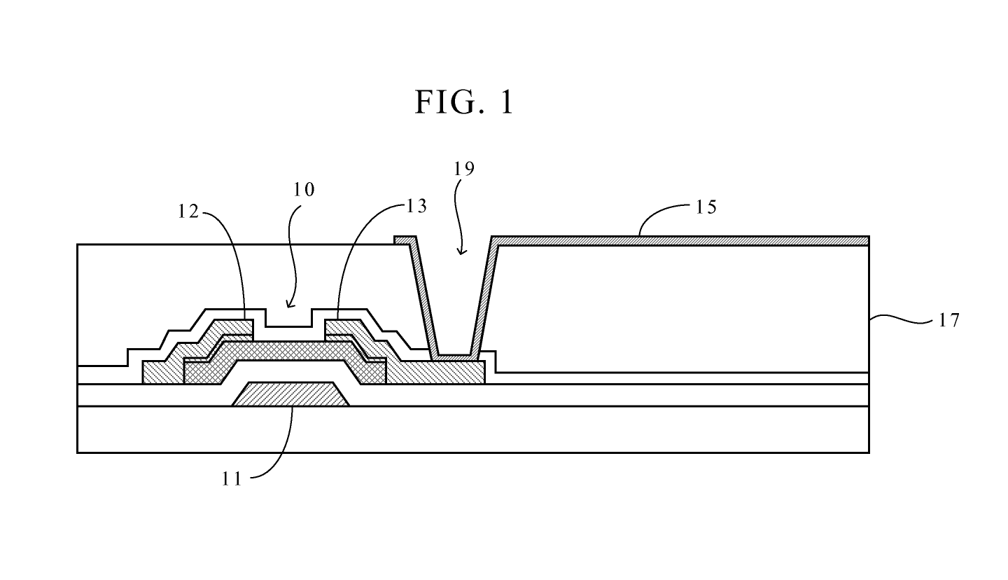

### DETAILED DESCRIPTION OF THE INVENTION

Descriptions of the following embodiments refer to attached drawings which are utilized to exemplify specific embodiments.

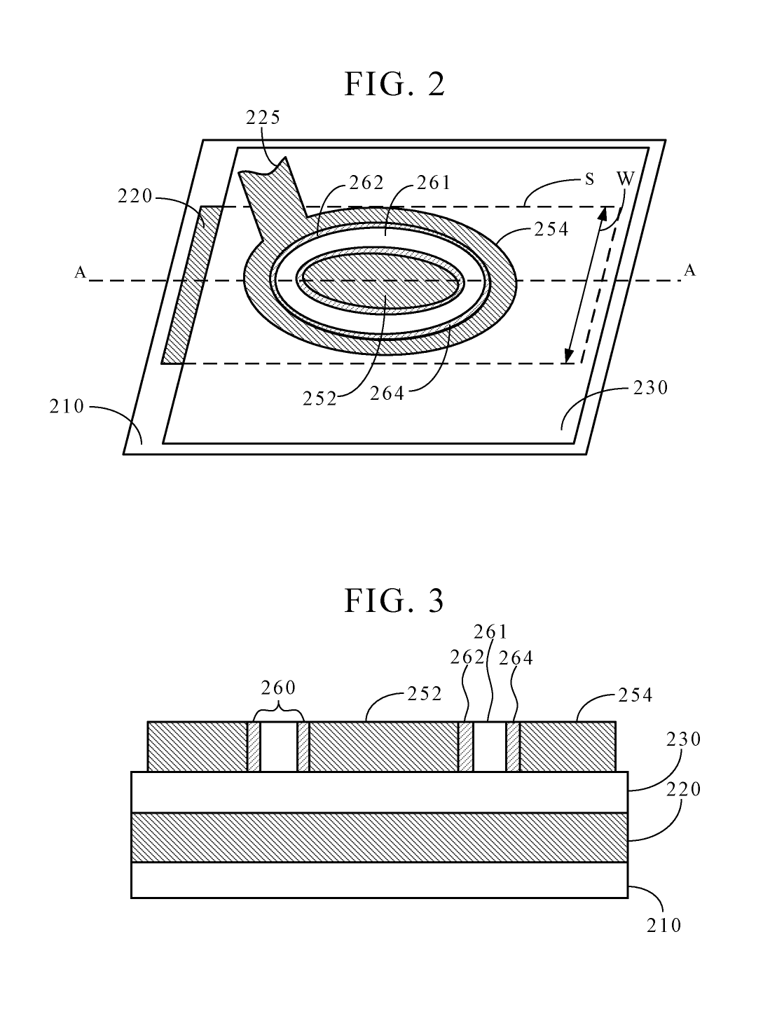

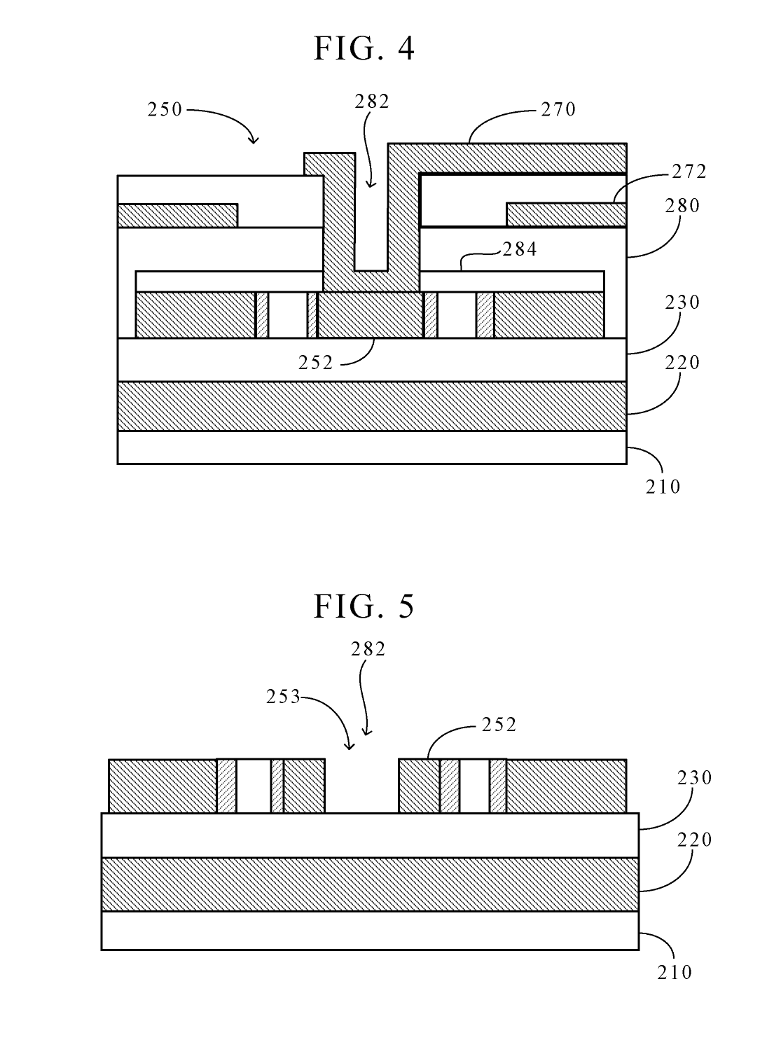

Referring to FIG. 2 to FIG. 4, FIG. 2 is a partial top view schematically illustrating a TFT-LCD pixel structure according to a preferred embodiment of the present invention; FIG. 3 is a sectional view along a dashed line A-A of FIG. 2; and FIG. 4 is a partial sectional view schematically illustrating a TFT-LCD pixel structure according to a preferred embodiment of the present invention. It should be noted that the above-mentioned drawings are just for explanation, and they are not depicted in real proportion.

As shown in the drawing, the TFT-LCD pixel structure of the embodiment includes a gate line 220, a TFT switch 250, and a pixel electrode 270 which are formed on a substrate 210. As shown in FIG. 2, the TFT switch 250 of the embodiment includes a circular drain 252, an annular semiconductor layer 260, an annular source 254, and a protective layer 280.

As shown in FIG. 3, the circular drain 252 is insulatively formed on the gate line 220. Specifically, the gate line 220 has a gate insulation (GI) layer 230 that is disposed thereon, and the circular drain 252 is formed on the gate insulation layer 230.

As shown in FIG. 2 and FIG. 3, the annular semiconductor layer 260 is disposed around the circular drain 252 and contacts an outer edge of the circular drain 252. In addition, the annular source 254 is disposed around the annular semiconductor layer 260 and contacts an outer edge of the annular semiconductor layer 260. Specifically, the annular semiconductor layer 260 is utilized as a conduction channel of the circular drain 252 and the annular source 254.

In the embodiment, the circular drain 252, the annular semiconductor layer 260, and the annular source 254 are disposed on the same plane. That is to say, the circular drain 252, the annular semiconductor layer 260, and the annular source 254 have the same thickness. It is worth mentioning that the circular drain 252, the annular semiconductor layer 260, and the annular source 254 appear a structure of concentric circles, and the center of the concentric circles is positioned at the center of the circular drain 252. However, the present invention does not limit the structure of concentric circles, and other structures such as ellipses, rectangles and so on are also within the scope of the present invention. More specifically, the drain and source may be irregularly shaped, so as to enlarge the contact area of the semiconductor layer between two electrodes, thereby increasing charging capability.

As shown in FIG. 2 and FIG. 3, furthermore, the annular semiconductor layer 260 includes an annular active layer 261, a first annular ohmic contact layer 262, and a second annular ohmic contact layer (N+ doped amorphous silicon) 264. Preferably, the annular active layer 261 is made of amorphous silicon (a-Si), and the first annular ohmic contact layer 262 and the second annular ohmic contact layer 264 are made of n+ a-Si. The first annular ohmic contact layer 262 is disposed on an inner edge of the annular active layer 261 and utilized to contact the circular drain 252. The second annular ohmic contact layer 264 is disposed on an outer edge of the annular active layer 261 and utilized to contact the annular source 254.

As shown in FIG. 2, the gate line has a predetermined width W and defines a strip of shaded region S. More specifically, the circular drain 252, the annular semiconductor layer 260 and the annular source 254 are located within the strip of shaded region S. In addition, the gate line 220 has a gate insulation layer 230 disposed thereon, and the circular drain 252, the annular semiconductor layer 260, and the annular source 254 are formed on the gate insulation layer 230. Therefore, the TFT switch 250 of the embodiment does not occupy translucent area, thereby maximizing the aperture ratio of the pixel.

As shown in FIG. 4, the protective layer 280 is formed on the circular drain 252, the annular semiconductor layer 260, and the annular source 254, The protective layer 280 herein defines a via hole 282 on the circular drain 252, and the pixel electrode 270 is electrically coupled to the circular drain 252 through the via hole 282. It is worth mentioning that there is a passivation layer 284 that is disposed between the protective layer 280 as well as the circular drain 252, annular semiconductor layer 260 and annular source 254. In the embodiment, a size of the via hole 282 is about equal to a size of the circular drain 252. That is to say, the via hole 282 is circular viewed from the top. However, in other embodiments, the shapes of the via hole and the drain may be different, as long as the pixel electrode 270 can contact the drain. Moreover, since the via hole 282 is located at the center of the TFT switch 250 and does not extend to a pixel display area outside the TFT switch 250, the aperture ratio can be maximized.

It is worth mentioning that there is a common electrode 272 that is disposed on the protective layer 280, and it can work with the pixel electrode 270 to form an In-Plane-Switching (IPS) pixel structure.

Referring to FIG. 5, FIG. 5 is a partial sectional view illustrating another embodiment. In another embodiment, the circular drain 252 defines an opening 253 at the center of the circular drain 253, and the opening 253 is connected to the via hole 282, so that the contact area between the pixel electrode 270 on the via hole 282 and the drain 252 increases, so as to further enhance the charging capability of the pixel electrode 270. Similarly, the present invention does not limit the size and shape of the opening 253, as long as the pixel electrode 270 contacts the drain 252.

What follows is a detail of a TFT-LCD array substrate that includes the above-mentioned TFT-LCD pixel structure. Referring to FIG. 2 to FIG. 4, the TFT-LCD array substrate of the embodiment includes a plurality of gate lines 220, data lines 225, TFT switches 250, and pixel electrodes 270.

Similarly, each of TFT switches 250 includes a circular drain 252, an annular semiconductor layer 260, an annular source 254, and a protective layer 280. The circular drain 252 is insulatively formed on the gate line 220. The annular semiconductor layer 260 is disposed around the circular drain 252. The annular source 250 is disposed around the annular semiconductor layer 260. The protective layer 280 is formed on the circular drain 252, the annular semiconductor layer 260 and the annular source 254. The protective layer 280 herein defines a via hole 282 on the circular drain 252, and the pixel electrode 270 is electrically coupled to the circular drain 252 through the via hole 282. It is worth mentioning that the data line 225 of the embodiment is coupled to an outer edge of the annular source 254.

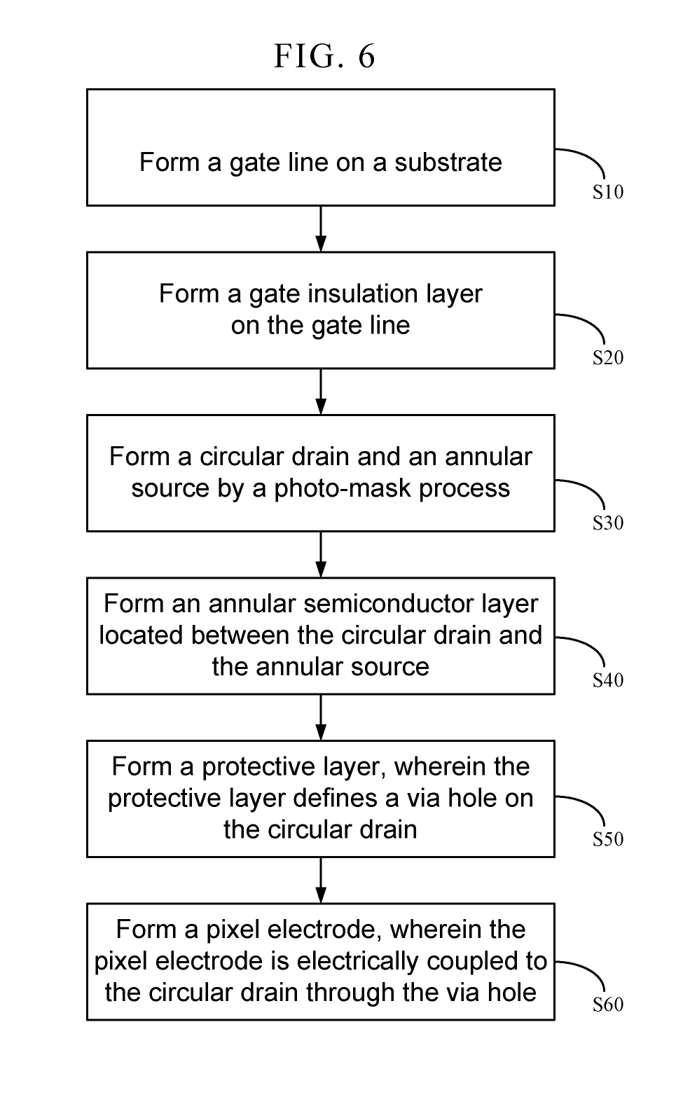

What follows is a detail of a method for manufacturing the TFT-LCD pixel structure of the embodiment. Referring to FIG. 6 and FIG. 2 to FIG. 4, FIG. 6 is a flow chart illustrating a method for manufacturing the TFT-LCD pixel structure according to a preferred embodiment of the present invention. The method for manufacturing the TFT-LCD pixel structure of the embodiment begins with step S10.

In step S10, the gate line 220 is formed on the substrate 210, and then execution resumes at step S20. In step S20, the gate insulation layer 230 is formed on the gate line 220, and then execution resumes at step S30. The step is well-known to a person skilled in the art, so no further detail will be provided herein.

In step S30, the circular drain 252 and the annular source 252 that is disposed around the circular drain 252 are formed on the gate insulation layer 230 by a photo-mask process, and then execution resumes at step S40.

In step S40, the annular semiconductor layer 260 that is located 254 between the circular drain 252 and the annular source 254 is formed on the gate insulation layer 260, and then execution resumes at step S50.

In step S50, the protective layer 280 that is located on the circular drain 252, the annular semiconductor layer 260 and the annular source 254 is formed, in which the protective layer 280 defines the via hole 282 on the circular drain 252, and then execution resumes at step S60.

In step S60, the pixel electrode 270 is formed on the protective layer 280, in which the pixel electrode 270 is electrically coupled to the circular drain 252 through the via hole 282.

Furthermore, as shown in FIG. 2, the step of forming the annular semiconductor layer 260 in step S40 specifically includes: forming an ohmic contact layer by a coating process; patterning the ohmic contact layer to form the first annular ohmic contact layer 262 that contacts the outer edge of the circular drain 252 and the second annular ohmic contact layer 264 that contacts the inner edge of the annular source 254; and forming the annular active layer 261 located between the first annular ohmic contact layer 262 and the second annular ohmic contact layer 264.

In summary, the present invention arranges the source, drain and semiconductor layer on the same plane, and the source, drain and semiconductor layer of the TFT switch 250 appear the design of the concentric circles. Then the circular drain 252, annular semiconductor layer 260 and annular source 254 of the present invention are disposed on the gate line 220, thereby enhancing the aperture ratio. In addition, the circular drain 252 and the annular source 254 of the present invention increase the area of the conduction channel, thereby enhancing the charging capability of the pixel electrode 270.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A TFT-LCD array substrate, comprising a plurality of gate lines, data lines, TFT switches and pixel electrodes formed on the substrate, each of the TFT switches comprising:
a circular drain insulatively formed on the gate line;
an annular semiconductor layer disposed around the circular drain;
an annular source disposed around the annular semiconductor layer, wherein the data line is coupled to an outer edge of the annular source; and
a protective layer formed on the circular drain, the annular semiconductor layer and the annular source, wherein the protective layer defines a via hole on the circular drain, and the pixel electrode is electrically coupled to the circular drain through the via hole.

2. The TFT-LCD array substrate according to claim 1, wherein a size of the via hole is about equal to a size of the circular drain.

3. The TFT-LCD array substrate according to claim 1, wherein the gate line has a predetermined width and defines a strip of shaded region.

4. The TFT-LCD array substrate according to claim 3, wherein the circular drain, the annular semiconductor layer and the annular source are located within the strip of shaded region.

5. The TFT-LCD array substrate according to claim 1, wherein the annular semiconductor layer comprises:
an annular active layer;
a first annular ohmic contact layer, disposed on an inner edge of the annular active layer, utilized to contact the circular drain; and
a second annular ohmic contact layer, disposed on an outer edge of the annular active layer, utilized to contact the annular source.

6. A TFT-LCD pixel structure, comprising a gate line, a TFT switch and a pixel electrode formed on a substrate, the TFT switch comprising:
a circular drain insulatively formed on the gate line;
an annular semiconductor layer disposed around the circular drain;
an annular source disposed around the annular semiconductor layer; and
a protective layer formed on the circular drain, the annular semiconductor layer and the annular source, wherein the protective layer defines a via hole on the circular drain, and the pixel electrode is electrically coupled to the circular drain through the via hole.

7. The TFT-LCD pixel structure according to claim 6, wherein a size of the via hole is about equal to a size of the circular drain.

8. The TFT-LCD pixel structure according to claim 7, wherein the via hole is circular.

9. The TFT-LCD pixel structure according to claim 6, wherein the gate line has a predetermined width and defines a strip of shaded region.

10. The TFT-LCD pixel structure according to claim 9, wherein the circular drain, the annular semiconductor layer and the annular source are located within the strip of shaded region.

11. The TFT-LCD pixel structure according to claim 10, wherein the gate line has a gate insulation layer disposed thereon, and the circular drain, annular semiconductor layer and annular source are formed on the gate insulation layer.

12. The TFT-LCD pixel structure according to claim 6, wherein the circular drain defines an opening at a center of the circular drain, and the opening is connected to the via hole.

13. The TFT-LCD pixel structure according to claim 6, wherein the annular semiconductor layer comprises:
an annular active layer;
a first annular ohmic contact layer, disposed on an inner edge of the annular active layer, utilized to contact the circular drain; and
a second annular ohmic contact layer, disposed on an outer edge of the annular active layer, utilized to contact the annular source.

14. A method for manufacturing a TFT-LCD pixel structure, comprising the steps of:
forming a gate line on a substrate;
forming a gate insulation layer on the gate line;
forming a circular drain and an annular source disposed around the circular drain on the gate insulation layer by a photo-mask process;
forming an annular semiconductor layer located between the circular drain and the annular source on the gate insulation layer;
forming a protective layer located on the circular drain, the annular semiconductor layer and the annular source, wherein the protective layer defines a via hole on the circular drain; and
forming a pixel electrode on the protective layer, wherein the pixel electrode is electrically coupled to the circular drain through the via hole.

15. The method according to claim 14, wherein the step of forming the annular semiconductor layer comprises:
forming an ohmic contact layer by a coating process;
patterning the ohmic contact layer to form a first annular ohmic contact layer that contacts an outer edge of the circular drain and a second annular ohmic contact layer that contacts an inner edge of the annular source; and
forming an annular active layer located between the first annular ohmic contact layer and the second annular ohmic contact layer.
